(19) United States
(12) Patent Application Publication
(10) Pub. No.: US 2008/0179751 A1
(43) Pub. Date: Jul. 31, 2008

(54) MANUFACTURING METHOD OF SEMICONDUCTOR DEVICES AND SEMICONDUCTOR DEVICE MANUFACTURED THEREBY

(75) Inventors: Tomoyuki Kitani, Yokohama-shi (JP); Tomohiro Iguchi, Kawasaki-shi (JP); Masako Hirahara, Yokohama-shi (JP); Hideo Nishiuchi, Kawasaki-shi (JP); Akira Tojo, Yokohama-shi (JP); Taizo Tomioka, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/017,929

(22) Filed: Jan. 22, 2008

(30) Foreign Application Priority Data
Jan. 25, 2007 (JP) 2007-015179

(51) Int. Cl. H01L 23/29; H01L 21/304

(52) U.S. Cl. 257/762; 438/465; 257/E23.118; 257/E21.238

(57) ABSTRACT

A manufacturing method for semiconductor devices includes a process of forming a conductive layer 4 on the other principle surface of a semiconductor wafer 10 having circuit elements 2 formed in one principle surface of the semiconductor wafer, a process of forming a protecting layer 5 on at least a part of the conductive layer, the protecting layer 5 being made from material having hard-to-shave characteristics in comparison with the conductive layer and a process of cutting the semiconductor wafer 10 into pieces with respect to each of the semiconductor devices 1. By the manufacturing method, each semiconductor device 1 is provided with a semiconductor substrate 3 having the circuit elements 2 formed in one principle surface of the semiconductor substrate 3, the conductive layer 4 formed on the other principle surface of the semiconductor substrate 3 and the protecting layer 5 formed on the conductive layer 4 in lamination to have hard-to-shave characteristics in comparison with the conductive layer 4.

### BACKGROUND OF THE INVENTION

1. Field of the Invention

The present invention relates to a manufacturing method of semiconductor devices and a semiconductor device manufactured by the above method. More particularly, it relates to a method of manufacturing semiconductor devices by flip chip bonding using ultrasonic vibration and the so-manufactured semiconductor device.

2. Description of the Related Art

In mounting a semiconductor device on a wiring substrate or a lead frame through flip chip bonding, soldering and conductive adhesive have been used up to this day. Additionally, flip chip bonding using ultrasonic vibration is also known in Japanese Patent Publication Laid-open No. H08-45994.

In the semiconductor device, circuit elements are built in a semiconductor substrate while the circuit elements are electrically connected with each other through conductive silicon forming the semiconductor substrate. Here, it is noted that silicon has a higher electric resistivity than that of metals.

Therefore, in a semiconductor device required with a small electric resistance, as typified by a power transistor, circuit elements are formed in one principle surface of the semiconductor substrate, while a metal layer of smaller electrical resistivity than silicon's is formed on the other principle surface on the opposite side of the former principle surface for the purpose of reducing an electrical resistance for current between the circuit elements.

FIG. 1 is a front view of an arrangement to implement flip chip bonding using ultrasonic vibration against a semiconductor device having a metal layer formed thereon. In the illustrated example, two circuit elements 102 are formed in a semiconductor substrate 101 forming a semiconductor device 100, on the side of one principle surface of the substrate 101. The semiconductor device 100 further has a metal layer 103 formed on the other principle surface on the opposite side of the circuit elements 102. Corresponding to the circuit elements 102, two bumps 104 for external connection of the elements 102 are arranged on the former principle surface of the substrate 101. The metal layer 103 is made of aluminum, copper and so on.

In order to mount the semiconductor device 100 on the wiring substrate 105 by flip chip bonding using ultrasonic vibration, the wiring substrate 105 is firstly mounted on a work holder (not shown). Then, the semiconductor device 100 is arranged in a manner so that the bumps 104 abut on the wiring substrate 105 while a bonding tool 106 for generating ultrasonic vibration abuts on the metal layer 103. When generating ultrasonic vibration for the semiconductor device 100, the bonding tool 106 is pressed on the device 100 while self-vibrating in the direction of arrow A.

However, the illustrated flip chip bonding for the semiconductor device 100 has a problem as follows.

In the bonding tool 106, its surface in abutment with the metal layer 103 is formed with irregularities 107. Accordingly, when applying ultrasonic vibration to the semiconductor device 100, shavings 108 are produced since the metal layer 103 is shaved by the irregularities 107 of the bonding tool 106. Consequently, the produced shavings 108 stick to the bonding tool 106 so as to fill up with the irregularities 107.

Due to the adhesion of the shavings 108 on the bonding tool 106, depending on the degree of adhesion, the application of ultrasonic vibration from the tool 6 to the semiconductor device 100 varies in terms of the degree of impression. Thus, due to variations in the degree of impression, the mounting state of the semiconductor device 100 on the wiring substrate 105 changes with respect to each device 100, causing so-assembled semiconductor installations to be varied in quality.

### SUMMARY OF THE INVENTION

In the above-mentioned situation, it is an object of the present invention to suppress a variation in the quality of the assembled semiconductor installations due to the adhesion of shavings to the bonding tool. More specifically, when mounting a semiconductor device having a conductive layer formed on a substrate surface to reduce an electrical resistance between circuit elements in the substrate by means of flip chip bonding using ultrasonic vibration, the object of the present invention is to prevent the conductive layer from being shaved by the bonding tool.

In order to attain the above object, according to a first aspect of the present invention, there is provided a manufacturing method for semiconductor devices, comprising the steps of: forming a conductive layer on one principle surface of a semiconductor wafer having a plurality of circuit elements formed in an other principle surface of the semiconductor wafer; forming a protecting layer on at least a part of the conductive layer, the protecting layer being made from material having hard-to-shave characteristics in comparison with the conductive layer; and cutting the semiconductor wafer into pieces with respect to each of the semiconductor devices.

According to a second aspect of the present invention, there is also provided a manufacturing method for semiconductor devices, comprising the steps of: forming a recess on one principle surface of a semiconductor wafer having a plurality of circuit elements formed in an other principle surface of the semiconductor wafer, with respect to each of the semiconductor devices assuming that the semiconductor wafer is cut into pieces for the semiconductor devices; forming a conductive layer in the recess, the conductive layer having a thickness smaller than a depth of the recess; and cutting the semiconductor wafer into the pieces with respect to each of the semiconductor devices.

Additionally, according to a third aspect of the present invention, there is provided a semiconductor device comprising: a semiconductor substrate having a plurality of circuit elements formed in one principle surface of the semiconductor substrate; a conductive layer formed on an other principle surface of the semiconductor substrate; and a protecting layer formed on the conductive layer in lamination to have hard-to-shave characteristics in comparison with the conductive layer.

Still further, according to a fourth aspect of the present invention, there is provided a semiconductor device comprising: a semiconductor substrate having a plurality of circuit elements formed in one principle surface of the semiconductor substrate; a recess formed on an other principle surface of the semiconductor substrate; and a protecting layer formed in the recess to have a thickness smaller than a depth of the recess.

### BRIEF DESCRIPTION OF THE DRAWINGS

FIG. 1 is a front view of an arrangement to explain an occurrence of shavings when mounting a conventional semiconductor device on a wiring substrate by flip chip bonding using ultrasonic vibration;

FIG. 2 is a front view of a semiconductor device in accordance with a first embodiment view of the invention;

FIG. 3 is a front view showing the process of mounting the semiconductor device on the wiring substrate by flip chip bonding using ultrasonic vibration;

FIG. 4 is a flow chart to explain the manufacturing process of the semiconductor device;

FIGS. 5A to 5J are process diagrams to explain the manufacturing process of the semiconductor device;

FIG. 6 is a perspective view showing a semiconductor wafer having conductive layers and protecting layers formed thereon;

FIG. 7 is a front view of a semiconductor device in accordance with a second embodiment of the present invention;

FIG. 8 is a front view showing the process of mounting the semiconductor device on the wiring substrate by flip chip bonding using ultrasonic vibration;

FIG. 9 is a flow chart to explain the manufacturing process of the semiconductor device;

FIG. 10A to 10H are process diagrams to explain the manufacturing process of the semiconductor device; and

FIG. 11 is a perspective view showing a semiconductor wafer having depressions and conductive layers formed thereon.

### DETAILED DESCRIPTION OF THE PREFERRED EMBODIMENTS

Embodiments of the present invention will be described with reference to attached drawings.

### 1^{st}. Embodiment

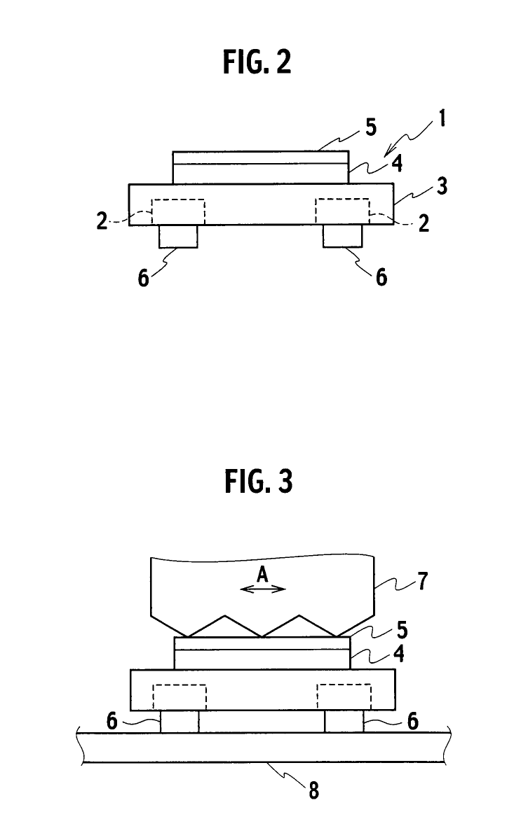

According to the first embodiment, a semiconductor device 1 has a semiconductor substrate 3 in which two circuit elements 2, such as FET, are formed, as shown in FIG. 2. Further, a conductive layer 4 is formed on one surface of the semiconductor substrate 3. A protecting layer 5 is formed on the conductive layer 4. On the other surface of the semiconductor substrate 3, two bumps (bump electrodes) 6 are arranged for external connection of the circuit elements 2, respectively. The semiconductor substrate 3 is generally made of silicon.

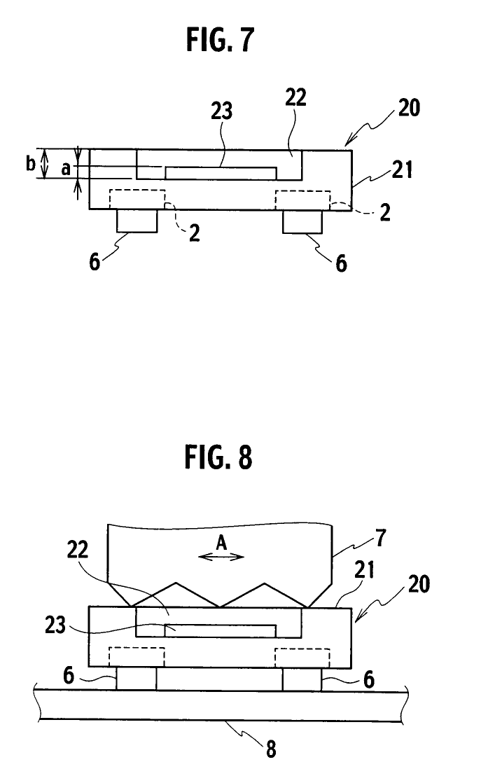

The semiconductor device 1 is provided by cutting a semiconductor wafer 10 (see FIG. 7) into a plurality of pieces having the size of appropriate dimensions. As shown in FIG. 7, the semiconductor wafer 10 has a plurality of circuit elements 2 formed on the side of one principle surface of the wafer 10. On the other principle surface of the wafer 10, conductive layers 4 are formed to enhance conductivity among the circuit elements 2. On the conductive layers 4, protecting layers 5 are formed to protect the layers 4, respectively. The conductive layer 4 and the protecting layer 5 in pairs are provided by firstly forming a uniform film and subsequently etching the film.

For material for the conductive layer 4, there is available any one of gold (Au), silver (Ag), copper (Cu) and aluminum (Al). Alternatively, alloy composed of two or more of these metals may be available for the conductive layer 4.

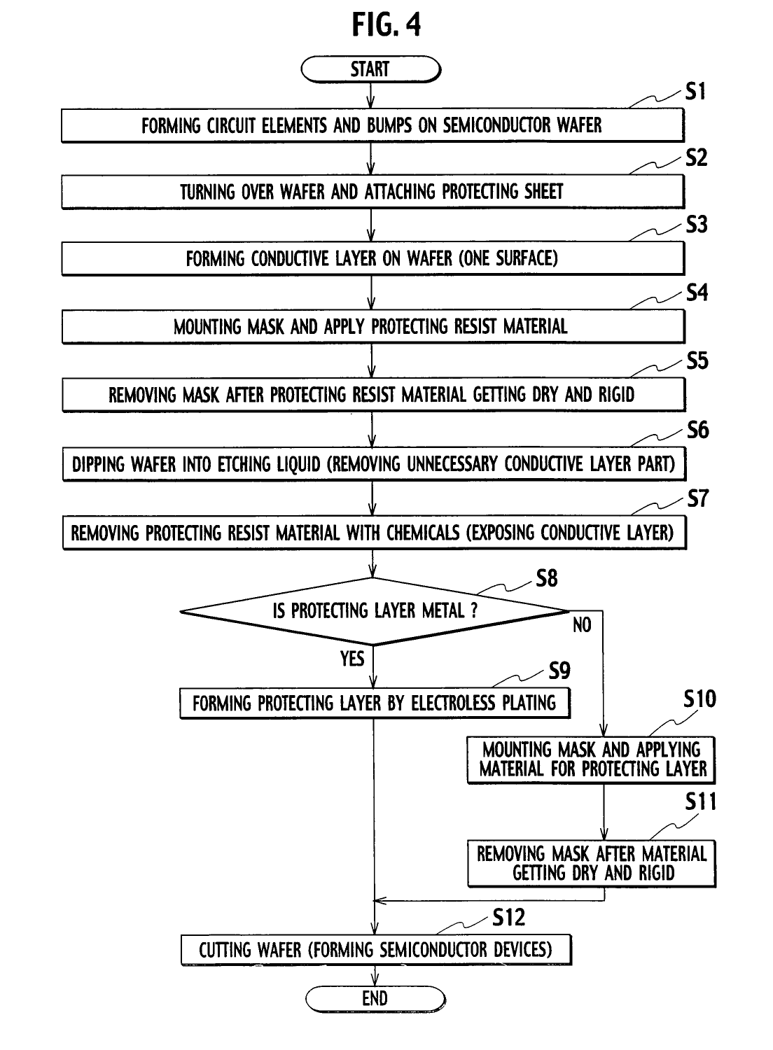

Taking account of contact with a boding tool (see FIG. 3) for applying ultrasonic vibration for later-mentioned flip chip bonding, the protecting layer 5 is made from material having hard-to-shave characteristics in comparison with the conductive layer 4. More specifically, there is available any one of nickel (Ni), titanium (Ti), tungsten (W), cobalt (Co) and platinum (Pt), each of which is harder than gold, silver, copper and aluminum. Alternatively, alloy composed of two or more of these metal elements may be available for the protecting layer 5. Besides these metal elements, there is available any one of phenol resin, epoxy resin, acrylic resin, imidic resin and amidic resin or their modified resin. Further, either glass having silica dioxide in main component or sintered ceramics having aluminum nitride in main component may be used for the protecting layer 5.

In order to fit the semiconductor device 1 onto the wiring substrate 8 by flip chip bonding using ultrasonic vibration, as shown in FIG. 3, the wiring substrate 8 is mounted on a work holder (not shown). Then, the semiconductor device 1 is arranged so that the bumps 6 abut on the wiring substrate 8. Next, a bolding tool 7 for applying ultrasonic vibration is brought into contact with the protecting layer 5 of the semiconductor device 1. When applying ultrasonic vibration on the semiconductor device 1, the bolding tool 7 is pressed against the device 1 while being vibrated in the direction of arrow A in parallel with a packaging surface of the wiring substrate 8.

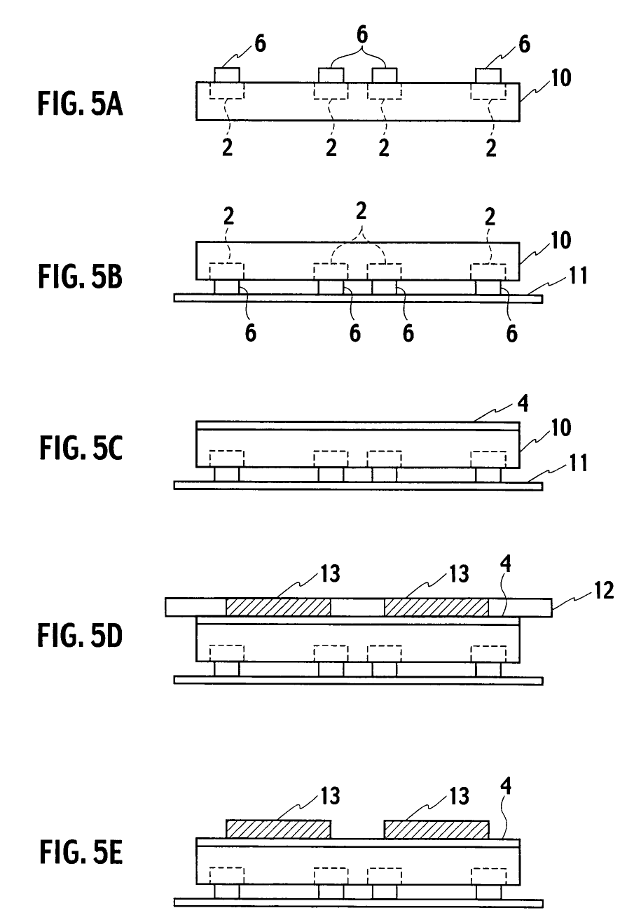

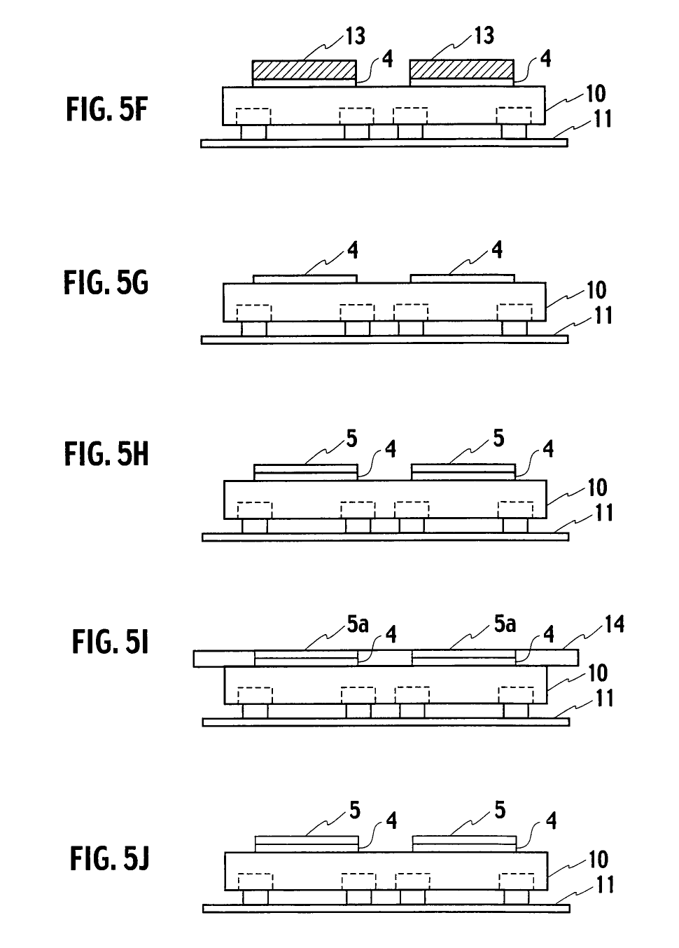

The manufacturing process of the semiconductor device 1 will be described with reference to FIG. 4 and FIGS. 5A to 5I.

As shown in FIG. 5A, it is performed at step S1 of FIG. 4 to form the circuit elements 2 and the bumps 6 on the semiconductor wafer 10. It is noted that when the semiconductor wafer 10 is cut into a plurality of semiconductor devices 1 in the final stage of the manufacturing process, a device portion corresponding to the semiconductor wafer 10 in each semiconductor device 1 is identical to the semiconductor substrate 3. In the semiconductor wafer 10, additionally, the circuit elements 2 and the bumps 6 are formed so that when the wafer 10 is cut into the semiconductor devices 1, the circuit elements 2 and the bumps 6 of each device 1 are present in the same positions throughout all devices 1.

Next, at step S2, it is performed to turn over the semiconductor wafer 10 formed with the circuit elements 2 and the bumps 6 and attach one wafer's surface on the side of the elements 2 and the bumps 6 onto a protecting sheet 11, as shown in FIG. 5B.

After attaching the semiconductor wafer 10 onto the protecting sheet 11, the conductive layer 4 is formed on the other wafer's surface on the opposite side of the circuit elements 2 and the bumps 6, as shown FIG. 5C (step S3). As for the method of forming the conductive layer 4, there may be adopted, for example, spattering and electroless plating. It is noted the conductive layer 4 is formed on the whole surface of the semiconductor wafer 10 at this stage. The conductive layer 4 is formed to have a thickness of 0.1˜50 μm.

After forming the conductive layer 4, it is performed at step S4 to lay a mask 12 on the conductive layer 4 and further apply a protecting resist material 13 on the mask 12. Consequently, the applied protecting resist material 13 enters into openings formed in the mask 12, as shown in FIG. 5D.

After the protecting resist material 13 gets dry and rigid, it is performed at step S5 to remove the mask 12 from the conductive layer 4. As a result of removing the mask 12, there is remained the protecting resist material (portions) 13 on the conductive layer 4, as shown in FIG. 5E.

At next step S6, it is performed to dip the semiconductor wafer 10 having the hardened protecting resist material 13 remained on the conductive layer 4 into etching liquid (not shown). Consequently, the conductive layer 4 but its portions beneath the protecting resist material 13 is removed from the semiconductor wafer 10 as shown in FIG. 5F.

After completing the etching process of leaving the conductive layer 4 in required portions, it is performed at step S7 to remove the protecting resist material 13 with chemicals, causing the conductive layer 4 to be exposed in the required portions, as shown in FIG. 5G. In the semiconductor wafer 10, the so-exposed conductive layer (portions) 4 are formed so that when the wafer 10 is cut into the semiconductor devices 1, the single conductive layer 4 of each device 1 is present in the same position throughout all devices 1.

After exposing the conductive layer 4 in the required portions, it is performed to form the protecting layer 5 on the conductive layer 4. As for the formation of the protecting layer 5, there are two forming methods depending on the material of the protecting layer 5, i.e. metal or nonmetal. Therefore, at step S8, it is executed to judge whether the protecting layer 5 should be made from metal or not.

If it is required to make the protecting layer 5 from metal (Yes at step S8), it is performed at step S9 to form the protecting layer 5 against the semiconductor wafer 10 of FIG. 5G by means of electroless plating. As a result of electroless plating, the protecting layer 5 of metal is formed only on the conductive layer 4. The protecting layer 5 is formed to have a thickness of 0.1˜20 μm.

If it is required to make the protecting layer 5 from nonmetal (No at step S8), it is performed at step S10 to lay a mask 14 having openings formed in respective positions corresponding to the conductive layer (portions) 4 on the semiconductor wafer 10 of FIG. 5G and further apply material 5a for the protecting layer 5, such as liquid resin and liquid ceramics, onto the mask 14, as shown in FIG. 5I.

After completing the application of the material 5a, it is performed at step S11 to wait for the hardening of the material 5a with its drying out and subsequently remove the mask 14 from the semiconductor wafer 10, as shown in FIG. 5J. In this way, the conductive layer 4 is covered with the protecting layer 5 as a result of hardening the material 5a.

In the first embodiment, as shown in FIG. 5H or 5J, the protecting layer 5 is formed on the whole area of the conductive layer 5. Alternatively, in the modification, the protecting layer 5 may be formed on a part of the conductive layer 4. That is, the positioning of the protecting layer 5 is not limited so long as it is formed on a conductive layer's area in contact with the bonding tool 7 at flip chip bonding.

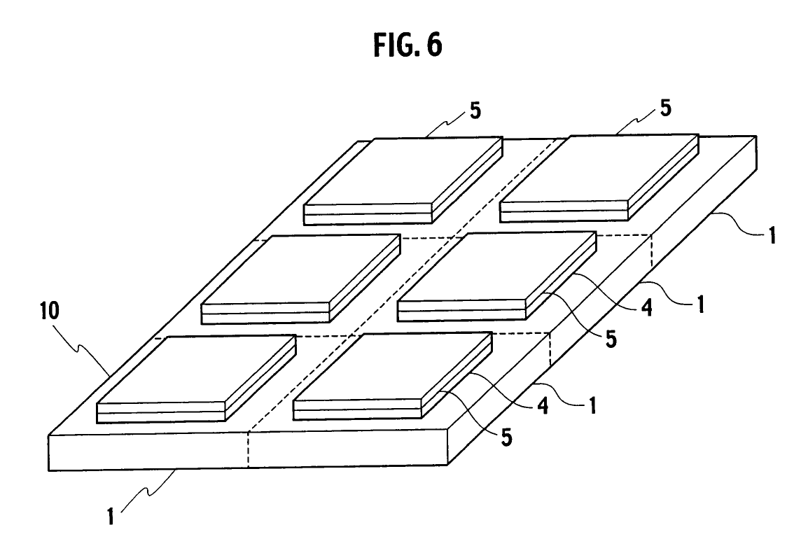

FIG. 6 illustrates the semiconductor wafer 10 where the conductive layer 4 and the protecting layer 5 are formed in lamination on each semiconductor device 1 in the above way. At final step S12, it is performed to cut the semiconductor wafer 10 of FIG. 6 into a plurality of semiconductor devices 1 through broken lines shown in the figure.

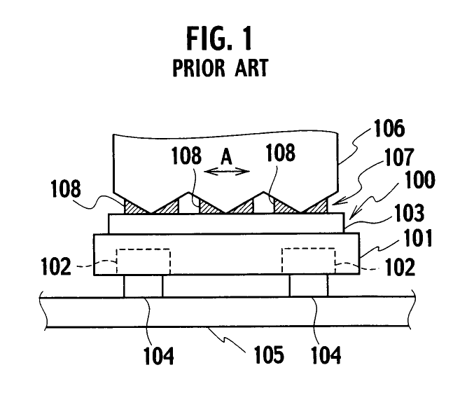

When mounting the semiconductor device 1 formed with the conductive layer 4 and the protecting layer 5 on the wiring substrate 8 by flip chip bonding using ultrasonic vibration in the above constitution, the bonding tool 7 for ultrasonic vibration is brought into contact with the protecting layer 5 as shown in FIG. 3. As the protecting layer 5 is made from material having hard-to-shave characteristics in comparison with the conductive layer 4, the protecting layer 5 is hard to be shaved in spite of vibration of the bonding tool 7 in abutment with the layer 5, so that the shavings 108 of FIG. 1 are difficult to be produced.

Therefore, it is possible to prevent the occurrence of the shavings 108 at contacts between the bonding tool 7 and the protecting layer 5 at flip chip bonding and also possible to prevent the degree of applying ultrasonic vibration from the bonding tool 7 onto the semiconductor device 1 from being varied due to adhesion of the shavings to the tool 7. Consequently, it is possible to maintain the application of ultrasonic vibration from the bonding tool 7 onto the individual semiconductor devices 1 uniformly and also possible to suppress a variation in the assembled state of the semiconductor devices 1 on the wiring substrates 8. That is, according to the first embodiment of the invention, it is possible to maintain the quality of the semiconductor installations obtained by mounting the semiconductor devices 1 on the wiring substrates 8, providing the semiconductor installations stabilized in quality.

Again, it is noted that the conductive layer 4 is not formed on the whole surface of the semiconductor wafer 10 but formed with respect to each area of the respective semiconductor devices 1 separately, as shown in FIG. 6. Therefore, in spite of a difference in the coefficient of linear expansion between the semiconductor wafer 10 and the conductive layer 4, it is possible to suppress cambering of the wafer 10 due to the above difference.

### 2^{nd}. Embodiment

The second embodiment of the present invention will be described with reference to FIG. 7 to FIG. 12. In the second embodiment illustrated therein, elements identical to those of the first embodiment will be indicated with the same reference numerals respectively and their overlapping descriptions are eliminated.

In the second embodiment, a semiconductor device 20 has a semiconductor substrate 21 in which two circuit elements 2, such as FET, and two bumps 6 are formed, as shown in FIG. 7. Further, the semiconductor substrate 21 is provided, on one surface thereof, with a recess 22 which includes a conductive layer 23 at the bottom of the recess 22. The conductive layer 23 has a thickness “a” smaller than a depth “b” of the recess 22. For material for the conductive layer 23, there is available any one of gold (Au), silver (Ag), copper (Cu) and aluminum (Al). Alternatively, alloy composed of two or more of these metals may be available for the conductive layer 4. The semiconductor substrate 21 is made of silicon.

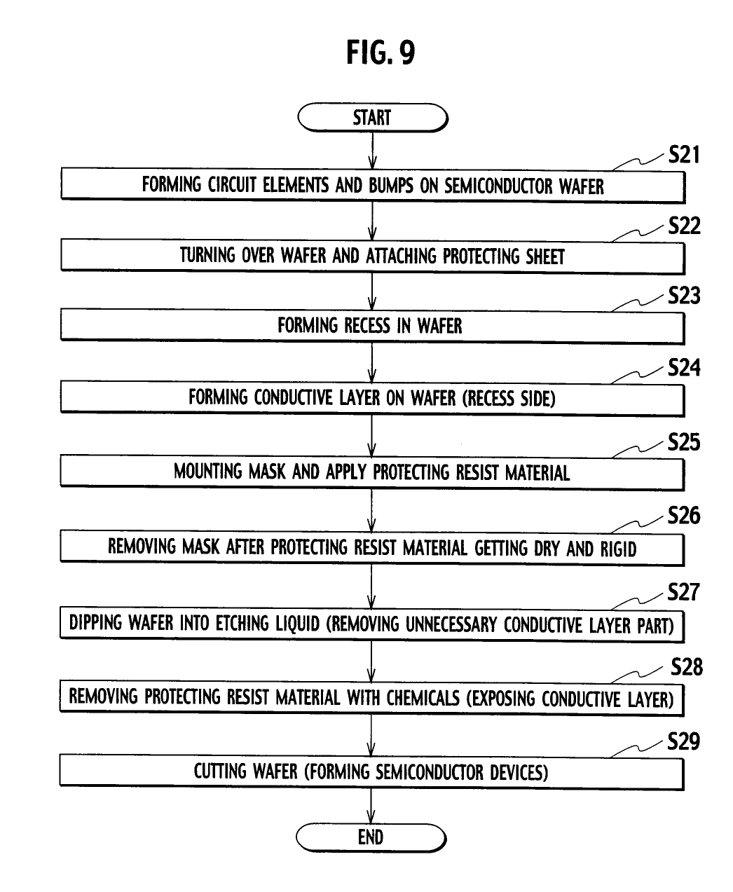

In order to fit the semiconductor device 20 onto the wiring substrate 8 by flip chip bonding using ultrasonic vibration, as shown in FIG. 8, the wiring substrate 8 is mounted on a work holder (not shown). Then, the semiconductor device 20 is arranged so that the bumps 6 abut on the wiring substrate 8. Next, the bolding tool 7 for applying ultrasonic vibration is brought into contact with the protecting layer 5 of the semiconductor device 20. When applying ultrasonic vibration on the semiconductor device 20, the bolding tool 7 is pressed against the device 20 while being vibrated in the direction of arrow A in parallel with a packaging surface of the wiring substrate 8.

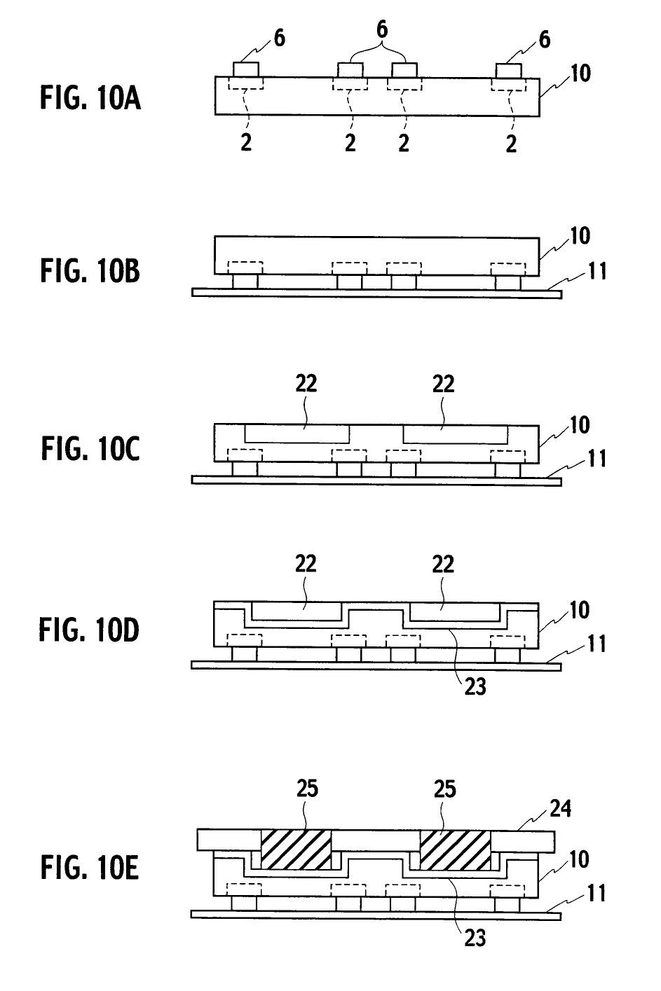

The manufacturing process of the semiconductor device 20 will be described with reference to FIGS. 9 to 11.

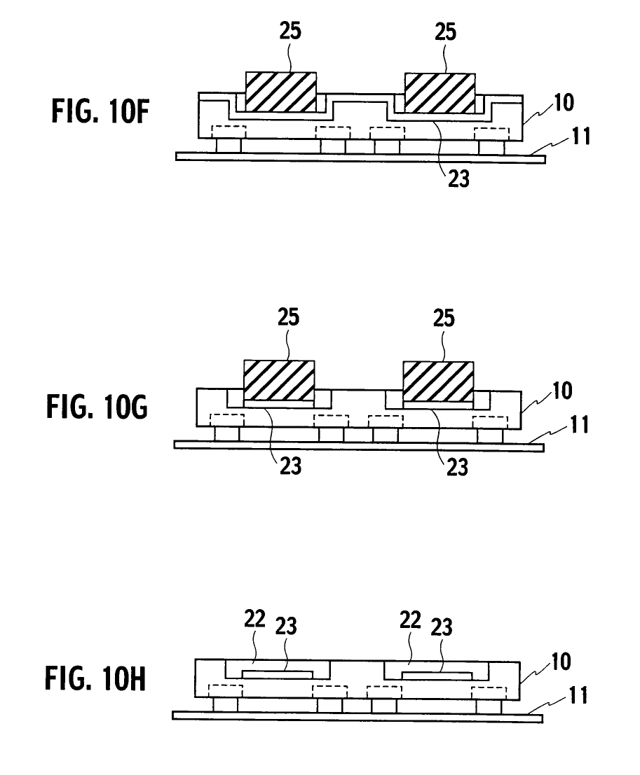

As shown in FIG. 10A, it is performed at step S21 of FIG. 9 to form the circuit elements 2 and the bumps 6 on the semiconductor wafer 10. It is noted that when the semiconductor wafer 10 is cut into a plurality of semiconductor devices 20 in the final stage of the manufacturing process, a device portion corresponding to the semiconductor wafer 10 in each semiconductor device 20 is identical to the semiconductor substrate 21. In the semiconductor wafer 10, additionally, the circuit elements 2 and the bumps 6 are formed so that when the wafer 10 is cut into the semiconductor devices 20, the circuit elements 2 and the bumps 6 of each device 1 are present in the same positions throughout all devices 20.

Next, at step S22, it is performed to turn over the semiconductor wafer 10 formed with the circuit elements 2 and the bumps 6 and attach one wafer's surface on the side of the elements 2 and the bumps 6 onto the protecting sheet 11, as shown in FIG. 10B.

After attaching the semiconductor wafer 10 onto the protecting sheet 11, it is performed at step S23 to form a plurality of recesses 22 in a wafer's surface on the opposite side of the protecting sheet 11 with the use of inert gas and etching liquid, as shown FIG. 10C. Each of the recesses 22 is formed so as to have a depth “b” of few micrometers (μm). These recesses 22 are formed so that when the wafer 10 is cut into the semiconductor devices 20, the single recess 22 of each device 1 are present in the same positions throughout all devices 20.

After forming the recesses 22, a conductive layer 23 is formed on the whole area of the wafer's surface on the side of the recesses 22, as shown FIG. 10D (step S24). As for the method of forming the conductive layer 23, there may be adopted, for example, electroless plating. The conductive layer 23 is formed to have a thickness “a” smaller than the depth “b” of each recess 22.

After forming the conductive layer 23, it is performed at step S25 to lay a mask 24 on the conductive layer 23 and further apply a protecting resist material 25 on the mask 24. The mask 24 is formed with openings in positions opposing the recesses 22. Consequently, the applied protecting resist material 25 enters into these openings, as shown in FIG. 10E.

After the protecting resist material 25 gets dry and rigid, it is performed at step S26 to remove the mask 24 from the conductive layer 23. As a result of removing the mask 24, there is remained the hardened protecting resist material (portions) 25 on the conductive layer 23, as shown in FIG. 5E.

At next step S27, it is performed to dip the semiconductor wafer 10, which has the hardened protecting resist material 25 remained on the conductive layer 22 in the recesses 22, into etching liquid (not shown). Consequently, the conductive layer 23 but its portions beneath the protecting resist material 25 is removed from the semiconductor wafer 10 as shown in FIG. 10G.

After completing the etching process of leaving the conductive layer 23 in required portions, it is performed at step S28 to remove the protecting resist material 25 with chemicals, causing the conductive layer 23 to be exposed in the required portions, as shown in FIG. 10H.

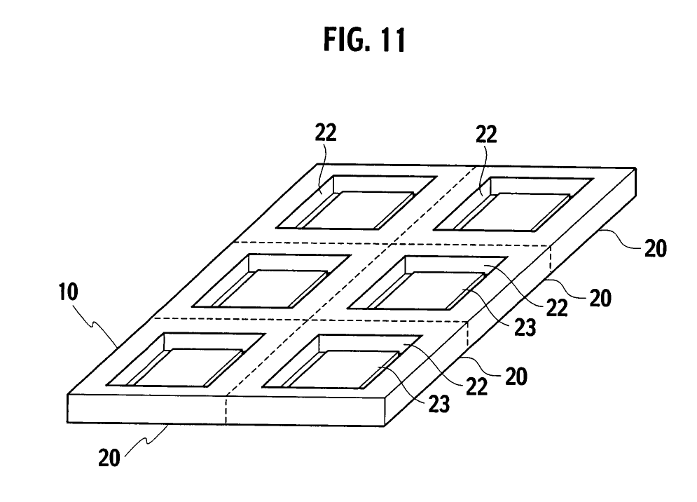

FIG. 11 illustrates the semiconductor wafer 10 where the conductive layer 23 is formed in each recess 22 in the above way. At final step S29, it is performed to cut the semiconductor wafer 10 of FIG. 11 into a plurality of semiconductor devices 20 through broken lines shown in the figure.

In the above constitution, when mounting the semiconductor device 20 formed with the recess 22 and the conductive layer 23 in the recess 22 on the wiring substrate 8 by flip chip bonding using ultrasonic vibration, the bonding tool 7 for ultrasonic vibration is brought into contact with a surface of the semiconductor substrate 21 on the side of the recess 22 and non-contact with the conductive layer 23 owing to the provision of the recess 22 as shown in FIG. 8. As the semiconductor substrate 21 is made from material having hard-to-shave characteristics in comparison with the conductive layer 23 made from gold, silver, copper or aluminum, the shavings are difficult to be produced in spite of vibration of the bonding tool 7 for flip chip bonding.

Therefore, it is possible to prevent the occurrence of the shavings at contacts between the bonding tool 7 and the conductive layer 23 at flip chip bonding and also possible to prevent the degree of applying ultrasonic vibration from the bonding tool 7 onto the semiconductor device 20 from being varied due to adhesion of the shavings to the tool 7. Consequently, it is possible to maintain the application of ultrasonic vibration from the bonding tool 7 onto the individual semiconductor devices 20 uniformly and also possible to suppress a variation in the assembled state of the semiconductor devices 20 on the wiring substrates 8. That is, according to the second embodiment of the invention, it is possible to maintain the quality of the semiconductor installations obtained by mounting the semiconductor devices 20 on the wiring substrates 8, providing the semiconductor installations stabilized in quality.

Again, it is noted that the conductive layer 23 is not formed on the whole surface of the semiconductor wafer 10 but formed in each recess 22 of the respective semiconductor devices 20 separately, as shown in FIG. 11. Therefore, in spite of a difference in the coefficient of linear expansion between the semiconductor wafer 10 and the conductive layer 23, it is possible to suppress cambering of the wafer 10 due to the above difference.

Although the present invention has been described above by reference to two embodiments of the invention, this invention is not limited to these embodiments and modifications will occur to those skilled in the art, in light of the teachings. The scope of the invention is defined with reference to the following claims.

This application is based upon the Japanese Patent Applications No. 2007-015179, filed on Jan. 25, 2007, the entire content of which is incorporated by reference herein.

What is claimed is:

1. A manufacturing method for semiconductor devices, comprising:
forming a conductive layer on one principle surface of a semiconductor wafer having a plurality of circuit elements formed in an other principle surface of the semiconductor wafer;
forming a protecting layer on at least a part of the conductive layer, the protecting layer being made from material having hard-to-shave characteristics in comparison with the conductive layer; and
cutting the semiconductor wafer into pieces with respect to each of the semiconductor devices.

2. The manufacturing method of claim 1, wherein:
the protecting layer is formed in a conductive layer's area with which a bonding tool for applying ultrasonic vibration to the semiconductor devices at flip chip binding of the semiconductor devices is brought into contact.

3. The manufacturing method of claim 1, wherein:
the conductive layer is made from one or more materials selected out of a group of gold, silver, copper and aluminum, and the protecting layer is made from any one of:
one or more materials selected out of a group of nickel, titanium, tungsten, cobalt and platinum;
either one selected out of a group of phenol resin, epoxy resin, acrylic resin, imidic resin and amidic resin or a modified resin of the selected one;
glass whose main component is silica dioxide; and
sintered ceramics whose main component is aluminum nitride.

4. The manufacturing method of claim 1, wherein:
the conductive layer is formed by means of spattering or electroless plating.

5. The manufacturing method of claim 3, wherein:
the protecting layer is made from metal, and
the protecting layer is formed by electroless plating.

6. A manufacturing method for semiconductor devices, comprising:
forming a recess on one principle surface of a semiconductor wafer having a plurality of circuit elements formed in an other principle surface of the semiconductor wafer, with respect to each of the semiconductor devices assuming that the semiconductor wafer is cut into pieces for the semiconductor devices;
forming a conductive layer in the recess, the conductive layer having a thickness smaller than a depth of the recess; and
cutting the semiconductor wafer into the pieces with respect to each of the semiconductor devices.

7. A semiconductor device comprising:
a semiconductor substrate having a plurality of circuit elements formed in one principle surface of the semiconductor substrate;
a conductive layer formed on an other principle surface of the semiconductor substrate; and
a protecting layer formed on the conductive layer in lamination to have hard-to-shave characteristics in comparison with the conductive layer.

8. The semiconductor device of claim 7, wherein:
the conductive layer is made from one or more materials selected out of a group of gold, silver, copper and aluminum, and
the protecting layer is made from any one of:
one or more materials selected out of a group of nickel, titanium, tungsten, cobalt and platinum;
either one selected out of a group of phenol resin, epoxy resin, acrylic resin, imidic resin and amidic resin or a modified resin of the selected one;
glass whose main component is silica dioxide; and
sintered ceramics whose main component is aluminum nitride.

9. A semiconductor device comprising:
a semiconductor substrate having a plurality of circuit elements formed in one principle surface of the semiconductor substrate;
a recess formed on an other principle surface of the semiconductor substrate; and
a protecting layer formed in the recess to have a thickness smaller than a depth of the recess.

10. The semiconductor device of claim 9, wherein:
the conductive layer is made from one or more materials selected out of a group of gold, silver, copper and aluminum, and
the protecting layer is made from any one of:
one or more materials selected out of a group of nickel, titanium, tungsten, cobalt and platinum;
either one selected out of a group of phenol resin, epoxy resin, acrylic resin, imidic resin and amidic resin or a modified resin of the selected one;
glass whose main component is silica dioxide; and
sintered ceramics whose main component is aluminum nitride.
